(19) United States
(12) Patent Application Publication
(10) Pub. No.: US 2026/0362998 A1
(43) Pub. Date: Nov. 12, 2026

(54) SUBSTRATE PROCESSING METHOD AND SUBSTRATE PROCESSING APPARATUS

(71) Applicant: Tokyo Electron Limited, Tokyo (JP)

(72) Inventors: Daichi ITO, Yamanashi (JP); Jun OGAWA, Yamanashi (JP)

(21) Appl. No.: 19/660,905

(22) Filed: Apr. 28, 2026

(30) Foreign Application Priority Data
May 12, 2025 (JP) 2025-079623

(51) Int. Cl. H10P 50/28; H10P 72/00

(52) U.S. Cl. CPC H10P 50/283; H10P 72/0421

(57) ABSTRACT

A substrate processing method for removing a part of a film to be etched formed on a surface of a substrate includes forming a reaction product through a reaction between a surface layer of the film to be etched and both of a fluorine-containing gas and a basic gas by supplying the fluorine-containing gas and the basic gas to the substrate while a temperature of the substrate is maintained at a first temperature, increasing the temperature of the substrate from the first temperature to a second temperature after the reaction product is formed, and sublimating the reaction product while the temperature of the substrate is maintained at the second temperature. The rate of temperature increase at which the temperature of the substrate is increased from the first temperature to the second temperature is less than 10°C per minute.

### CROSS-REFERENCE TO RELATED APPLICATIONS

This application claims priority to Japanese Patent Application No. 2025-079623, filed May 12, 2025, the entire content of which is incorporated herein by reference.

### BACKGROUND

### 1. Technical Field

The present disclosure relates to a substrate processing method and a substrate processing apparatus.

### 2. Description of Related Art

Japanese Patent No. 5661523 (hereinafter "Patent Document 1") discloses a technique for etching a silicon oxide film by forming ammonium silicofluoride through a reaction between a surface layer of the silicon oxide film and both of hydrofluoric acid gas and ammonia gas, and sublimating the ammonium silicofluoride.

### SUMMARY

A substrate processing method according to one aspect of the present disclosure is a substrate processing method for removing a part of a film to be etched formed on a surface of a substrate. The method includes forming a reaction product through a reaction between a surface layer of the film to be etched and both of a fluorine-containing gas and a basic gas by supplying the fluorine-containing gas and the basic gas to the substrate while a temperature of the substrate is maintained at a first temperature, increasing the temperature of the substrate from the first temperature to a second temperature after the reaction product is formed, and sublimating the reaction product while the temperature of the substrate is maintained at the second temperature. The rate of temperature increase at which the temperature of the substrate is increased from the first temperature to the second temperature is less than 10°C per minute.

### BRIEF DESCRIPTION OF THE DRAWINGS

FIG. 1 is a vertical cross-sectional view illustrating a substrate processing apparatus according to an embodiment;

FIG. 2 is a horizontal cross-sectional view illustrating the substrate processing apparatus according to the embodiment;

FIG. 3 is a flowchart illustrating a substrate processing method according to an embodiment;

FIG. 4 is a cross-sectional view (1) illustrating the substrate processing method according to the embodiment;

FIG. 5 is a cross-sectional view (2) illustrating the substrate processing method according to the embodiment;

FIG. 6 is a cross-sectional view (3) illustrating the substrate processing method according to the embodiment;

FIG. 7 is a cross-sectional view (4) illustrating the substrate processing method according to the embodiment;

FIG. 8 is a cross-sectional view (5) illustrating the substrate processing method according to the embodiment;

FIG. 9 is a graph illustrating an example of substrate temperature at each step of FIG. 3;

FIG. 10 is a graph illustrating another example of substrate temperature at each step of FIG. 3; and

FIG. 11 illustrates an arithmetic mean roughness of a surface of a silicon nitride film after etching.

### DETAILED DESCRIPTION

The present disclosure provides a technique for reducing surface roughness of a nitride film after etching.

Non-limiting exemplary embodiments of the present disclosure will be described below with reference to the accompanying drawings. In all of the accompanying drawings, the same or corresponding members or components are denoted by the same or corresponding reference numerals, and redundant descriptions will be omitted.

### Substrate Processing Apparatus

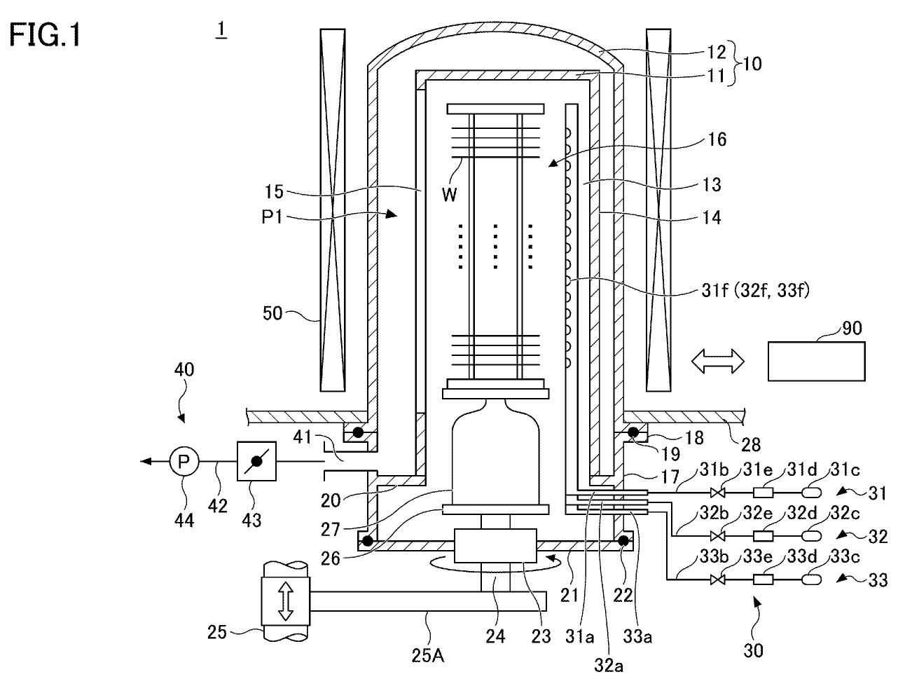

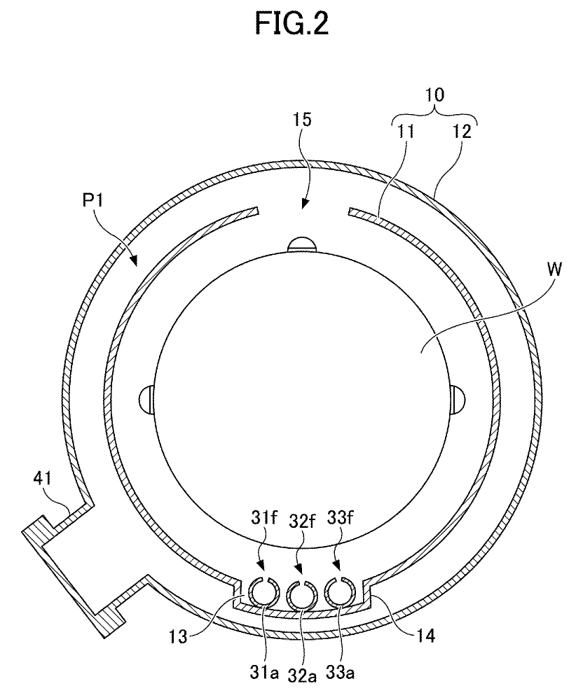

FIG. 1 is a vertical cross-sectional view illustrating a substrate processing apparatus 1 according to an embodiment. FIG. 2 is a horizontal cross-sectional view illustrating the substrate processing apparatus 1 according to the embodiment.

The substrate processing apparatus 1 is a batch-type apparatus which processes a plurality of substrates W, for example, 50 to 150 substrates W in a batch. The substrate W is, for example, a semiconductor wafer. The substrate processing apparatus 1 includes a processing chamber 10, a gas supply 30, an exhaust assembly 40, a heater 50, and a controller 90.

The processing chamber 10 can be depressurized internally. The processing chamber 10 accommodates a substrate W. The processing chamber 10 includes an inner cylinder 11 and an outer cylinder 12. The inner cylinder 11 has a cylindrical shape with a ceiling and an open bottom. The outer cylinder 12 also has a cylindrical shape with a ceiling and an open bottom and is configured to enclose the inner cylinder 11. The inner cylinder 11 and the outer cylinder 12 are formed of a heat-resistant material such as quartz. The inner cylinder 11 and the outer cylinder 12 have a double-cylinder structure coaxially arranged.

A housing part 13 for accommodating gas supply pipes is formed in the side wall of the inner cylinder 11 along a vertical direction. For example, a portion of the side wall of the inner cylinder 11 is formed to protrude outward, thereby forming an expanded portion 14, and the interior of the expanded portion 14 serves as the housing part 13.

A rectangular opening 15 is formed in the side wall of the inner cylinder 11 along the vertical direction. The opening 15 faces the housing part 13.

The opening 15 is a gas exhaust port formed to exhaust gas in the inner cylinder 11. The length of the opening 15 is the same as the length of a boat 16 or longer than the length of the boat 16.

The lower end of the processing chamber 10 is supported by a manifold 17 having a cylindrical shape. The manifold 17 is formed of, for example, stainless steel. A flange 18 is formed at the upper end of the manifold 17. The flange 18 supports the lower end of the outer cylinder 12. A sealing member 19 such as an O-ring is provided between the flange 18 and the lower end of the outer cylinder 12. The interior of the outer cylinder 12 is thereby maintained airtight.

A support 20 having an annular shape is provided on the upper inner wall of the manifold 17. The support 20 supports the lower end of the inner cylinder 11. A lid body 21 is airtightly attached to the opening of the lower end of the manifold 17 through a sealing member 22 such as an O-ring. Thus, the opening at the lower end of the processing chamber 10, namely the opening of the manifold 17, is airtightly closed. The lid body 21 is formed of, for example, stainless steel.

A rotary shaft 24 is provided penetrating the center of the lid body 21 through a magnetic fluid seal 23. The lower part of the rotary shaft 24 is rotatably supported by an arm 25A of an elevating mechanism 25 composed of a boat elevator.

A rotary plate 26 is provided at the upper end of the rotary shaft 24. The boat 16 for holding a plurality of substrates W is mounted on the rotary plate 26, with a quartz heat insulation table 27 provided between the boat 16 and the rotary plate 26. The boat 16 rotates by rotation of the rotary shaft 24. The boat 16 moves up and down together with the lid body 21 by raising and lowering the elevating mechanism 25, thereby allowing the boat 16 to be inserted into and removed from the processing chamber 10. The boat 16 can be accommodated in the processing chamber 10. The boat 16 holds the plurality of substrates W in a shelf-like manner. The boat 16 holds the plurality of substrates W substantially horizontally at intervals in the vertical direction.

The gas supply 30 is configured so as to introduce various process gases into the inner cylinder 11. The gas supply 30 includes a dichlorosilane gas supply 31, an ammonia gas supply 32, and a hydrogen fluoride gas supply 33.

The dichlorosilane gas supply 31 includes a gas supply pipe 31a inside the processing chamber 10, and a supply channel 31b outside the processing chamber 10. In the supply channel 31b, a dichlorosilane gas source 31c, a mass flow controller 31d, and a valve 31e are provided in this order from the upstream side to the downstream side in a gas flow direction. This configuration allows the supply timing of dichlorosilane gas in the gas source 31c to be controlled by the valve 31e, and the flow rate to be adjusted to a predetermined level by the mass flow controller 31d. Dichlorosilane gas flows into the gas supply pipe 31a from the supply channel 31b, and is discharged from the gas supply pipe 31a into the processing chamber 10. Dichlorosilane gas is an example of a silicon-containing gas.

The ammonia gas supply 32 is provided with a gas supply pipe 32a inside the processing chamber 10 and a supply channel 32b outside the processing chamber 10. In the supply channel 33b, a gas source 32c of ammonia gas, a mass flow controller 32d, and a valve 32e are provided in this order from the upstream side to the downstream side in a gas flow direction. This configuration allows the supply timing of ammonia gas in the gas source 32c to be controlled by the valve 32e, and the flow rate to be adjusted to a predetermined level by the mass flow controller 32d. Ammonia gas flows into the gas supply pipe 32a from the supply channel 32b, and is discharged from the gas supply pipe 32a into the processing chamber 10. Ammonia gas is an example of a nitride gas and a basic gas.

The hydrogen fluoride gas supply 33 includes a gas supply pipe 33a inside the processing chamber 10, and a supply channel 33b outside the processing chamber 10. The supply channel 33b is provided with a gas source 33c of hydrogen fluoride gas, a mass flow controller 33d, and a valve 33e in this order from the upstream side to the downstream side in a gas flow direction. This configuration allows the supply timing of hydrogen fluoride gas from the gas source 33c to be controlled by the valve 33e, and the flow rate to be adjusted to a predetermined level by the mass flow controller 33d. Hydrogen fluoride gas flows into the gas supply pipe 33a from the supply channel 33b, and is discharged from the gas supply pipe 33a into the processing chamber 10. Hydrogen fluoride gas is an example of a fluorine-containing gas.

The gas supply pipes 31a, 32a, and 33a are fixed to the manifold 17. The gas supply pipes 31a, 32a, and 33a are formed of, for example, quartz. The gas supply pipes 31a, 32a, and 33a extend linearly in the vertical direction in the vicinity of the inner cylinder 11, bend in an L-shape in the manifold 17 and extend in the horizontal direction, thereby penetrating the manifold 17. The gas supply pipes 31a, 32a, and 33a are provided side by side along the circumferential direction of the inner cylinder 11 and are formed at the same height.

A plurality of discharge ports 31f are provided in a portion of the gas supply pipe 31a located in the inner cylinder 11. The plurality of discharge ports 31f are provided at predetermined intervals along the vertical direction. The plurality of discharge ports 31f discharge gas horizontally toward the substrate W from the outside in the radial direction of the substrate W. The gas supply pipes 32a and 33a are also provided with a plurality of discharge ports 32f and 33f, respectively, similar to the gas supply pipe 31a.

The gas supply 30 may mix a plurality of kinds of gases and discharge the mixed gas from one gas supply pipe. The gas supply pipes 31a, 32a, and 33a may have shapes and arrangements different from each other. The gas supply 30 may further include a gas supply pipe for supplying another gas, for example, an inert gas.

The exhaust assembly 40 includes a gas outlet 41, an exhaust channel 42, a pressure regulating valve 43, and a vacuum pump 44. The gas outlet 41 is an upper side wall of the manifold 17 and is formed above the support 20. The exhaust channel 42 is connected to the gas outlet 41. The pressure regulating valve 43 is provided in the exhaust channel 42. The vacuum pump 44 is provided downstream of the pressure regulating valve 43 in the exhaust channel 42. The exhaust assembly 40 exhausts the gas in the processing chamber 10 by the vacuum pump 44 while the pressure in the processing chamber 10 is regulated by the pressure regulating valve 43. The gas in the inner cylinder 11 passes through the opening 15, a space P1 between the inner cylinder 11 and the outer cylinder 12, and the gas outlet 41 in this order, and is exhausted from the processing chamber 10.

The heater 50 is provided around the outer cylinder 12. The heater 50 is provided, for example, on a base plate 28. The heater 50 has a cylindrical shape so as to enclose the outer cylinder 12. The heater 50 includes, for example, a heating element and heats each substrate W in the processing chamber 10.

The controller 90 is an electronic circuit such as a CPU (central processing unit), an FPGA (field programmable gate array), and an ASIC (application specific integrated circuit). The controller 90 executes various control operations described herein by executing instruction codes stored in a memory or by designing a circuit for a special application.

### Substrate Processing Method

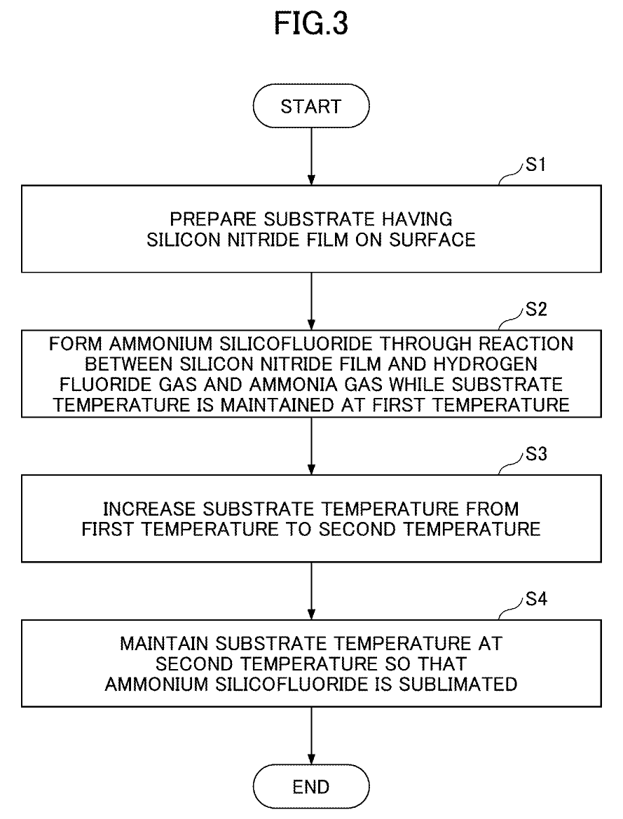

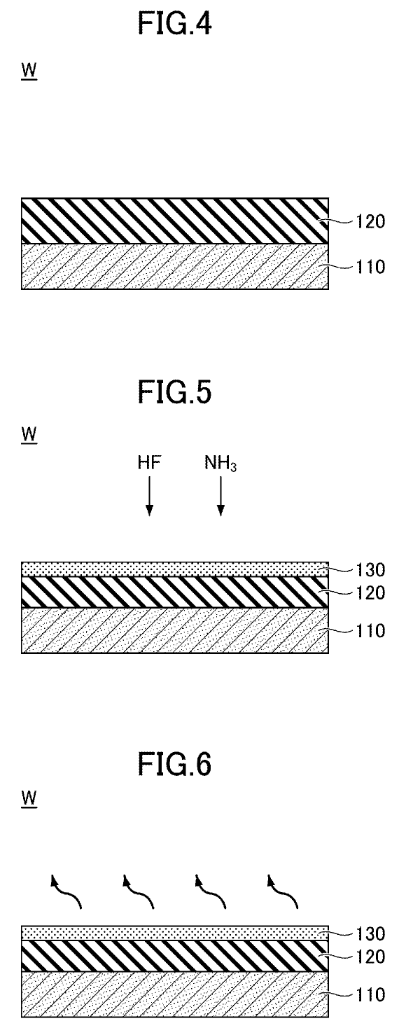

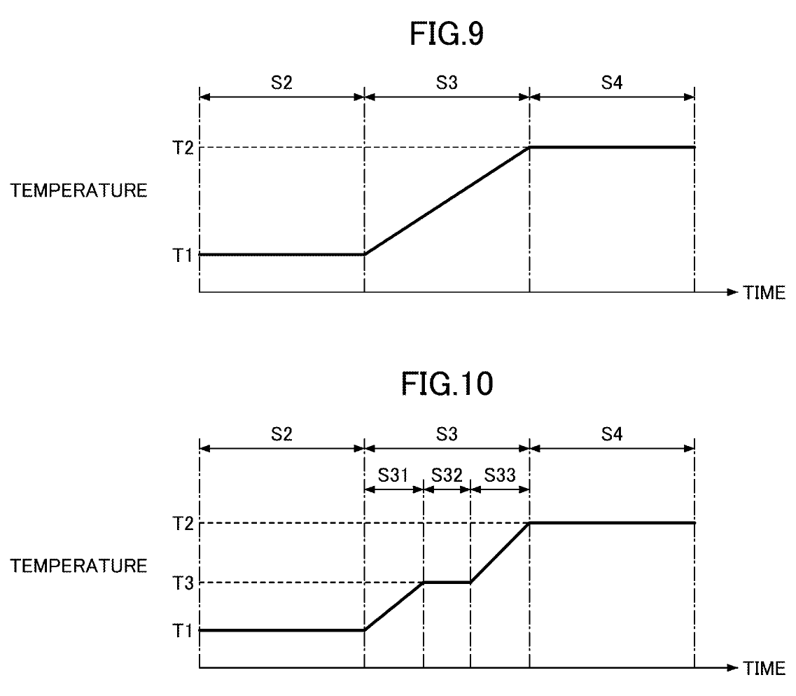

FIG. 3 is a flowchart illustrating a substrate processing method according to an embodiment. FIGS. 4-8 are cross-sectional views illustrating the substrate processing method according to the embodiment. FIG. 9 is a graph illustrating an example of a temperature of a substrate W in each step of FIG. 3. FIG. 10 is a graph illustrating another example of a temperature of a substrate W in each step of FIG. 3. The substrate processing method according to the embodiment includes step S1 through step S4 illustrated in FIG. 3.

In step S1, the controller 90 controls the substrate processing apparatus 1 in such a manner that the boat 16 holding the plurality of substrates W is loaded into the processing chamber 10 by raising the arm 25A, the opening at the lower end of the processing chamber 10 is airtightly closed by the lid body 21, and the inside of the processing chamber 10 is depressurized. As illustrated in FIG. 4, each substrate W includes a base substrate 110 and a silicon nitride film 120. The base substrate 110 is, for example, a silicon wafer. The silicon nitride film 120 is provided on the base substrate 110. The silicon nitride film 120 is an example of a film to be etched. The formation of the silicon nitride film 120 may be performed in the processing chamber 10. For example, the controller 90 controls the gas supply 30 and the heater 50 so as to non-simultaneously supply dichlorosilane gas and ammonia gas into the processing chamber 10 while the temperature of each substrate W in the processing chamber 10 is adjusted and maintained at a deposition temperature. Thus, the silicon nitride film 120 can be deposited on the base substrate 110. The deposition temperature may be 400° C. to 800° C., for example, 630° C. The controller 90 may control the gas supply 30 so as to simultaneously supply dichlorosilane gas and ammonia gas into the processing chamber 10 while the temperature of each substrate W in the processing chamber 10 is adjusted and maintained at the deposition temperature.

In step S2, as illustrated in FIGS. 9 and 10, the controller 90 controls the gas supply 30 and the heater 50 so as to simultaneously supply hydrogen fluoride gas and ammonia gas into the processing chamber 10 while the temperature of each substrate W in the processing chamber 10 is maintained at a first temperature T1. As illustrated in FIG. 5, a modified layer 130 containing ammonium silicofluoride [(NH₄)₂SiF₆], which is a reaction product, is thereby formed through a reaction between the surface layer of the silicon nitride film 120 and both of the hydrogen fluoride gas and the ammonia gas. The first temperature T1 may be equal to or greater than 50° C. and equal to or less than 100° C., for example, 75° C.

In step S3, the controller 90 controls the gas supply 30 and the heater 50 so as to increase the temperature of each substrate W in the processing chamber 10 from the first temperature T1 to a second temperature T2 while an inert gas such as nitrogen gas is supplied into the processing chamber 10. The second temperature T2 is a temperature equal to or greater than the temperature at which the ammonium silicofluoride sublimates. The second temperature T2 may be equal to or greater than 200° C., for example, 300° C.

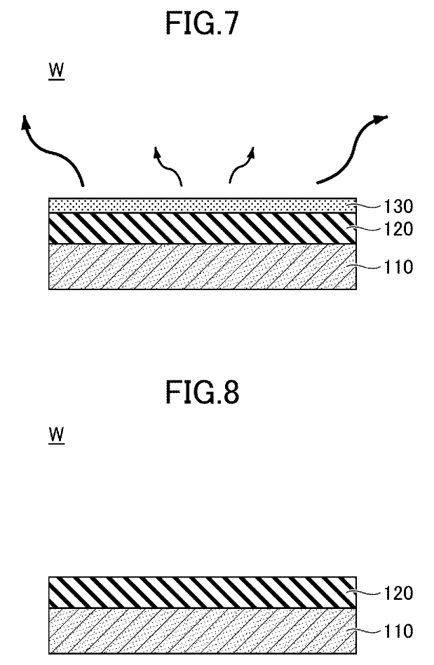

In step S3, for example, as illustrated in FIG. 9, the controller 90 controls the heater 50 so as to increase the temperature of each substrate W in the processing chamber 10 from the first temperature T1 to the second temperature at a constant rate of temperature increase. In this case, as the temperature of each substrate W is increased from the first temperature T1 to the second temperature T2, the ammonium silicofluoride contained in the modified layer 130 begins to sublimate. In step S3, the rate of temperature increase when the temperature of each substrate W is increased from the first temperature T1 to the second temperature T2 may be less than 10° C. per minute. In this case, temperature unevenness is less likely to occur in the surface of each substrate W when the temperature of each substrate W is increased. Therefore, as illustrated in FIG. 6, the ammonium silicofluoride contained in the modified layer 130 is easily sublimated uniformly in the surface of each substrate W. In contrast, when the temperature of each substrate W is increased from the first temperature T1 to the second temperature T2 at a rate of 10° C. per minute or greater, temperature unevenness is likely to occur in the surface of each substrate W due to the rapid temperature increase. Therefore, the ammonium silicofluoride contained in the modified layer 130 is difficult to sublimate uniformly in the surface of each substrate W. For example, as illustrated in FIG. 7, since the rate of temperature increase becomes higher from the center of each substrate W toward the edge, the ammonium silicofluoride contained in the modified layer 130 is more easily sublimated at positions farther from the center of the substrate W. In step S3, when the temperature of each substrate W is increased from the first temperature T1 to the second temperature T2, the rate of temperature increase may be 1° C. per minute or greater from the viewpoint of productivity.

In step S3, for example, as illustrated in FIG. 10, during the increase of the temperature of each substrate W from the first temperature T1 to the second temperature T2, the controller 90 controls the heater 50 so as to maintain the temperature of each substrate W in the processing chamber 10 at a third temperature T3, which is greater than the first temperature T1 and less than the second temperature T2, for a predetermined length of time. The third temperature T3 is, for example, an intermediate temperature between the first temperature T1 and the second temperature T2. First, the controller 90 increases the temperature of each substrate W in the processing chamber 10 from the first temperature T1 to the third temperature T3 (step S31). Next, the controller 90 controls the heater 50 to maintain the temperature of each substrate W in the processing chamber 10 at the third temperature T3 (step S32). Next, the controller 90 controls the heater 50 to increase the temperature of each substrate W in the processing chamber 10 from the third temperature T3 to the second temperature T2 (step S33). In this case, since the rapid temperature increase of each substrate W is reduced, temperature unevenness is less likely to occur in the surface of each substrate W when the temperature of each substrate W is increased. Therefore, as illustrated in FIG. 6, the ammonium silicofluoride contained in the modified layer 130 is easily sublimated uniformly in the surface of each substrate W. The time in step S32 may be a time until the temperature of each substrate W is stabilized to the third temperature T3. In this case, temperature unevenness is further less likely to occur in the surface of each substrate W when the temperature of each substrate W is increased. The rate of temperature increase in step S31 may be less than 10° C. per minute. In this case, temperature unevenness is less likely to occur in the surface of each substrate W when the temperature of each substrate W is increased from the first temperature T1 to the third temperature T3. The rate of temperature increase in step S33 may be less than 10° C. per minute. In this case, temperature unevenness is less likely to occur in the surface of each substrate W when the temperature of each substrate W is increased from the third temperature T3 to the second temperature T2. In step S3, when the temperature of each substrate W in the processing chamber 10 is increased from the first temperature T1 to the second temperature T2, the controller 90 may control the heater 50 so as to increase the temperature of each substrate W in a step-wise manner.

In step S4, the controller 90 controls the gas supply 30 and the heater 50 so as to maintain the temperature of each substrate W in the processing chamber 10 at the second temperature T2 while an inert gas such as nitrogen gas is supplied into the processing chamber 10. Thus, as illustrated in FIG. 8, the ammonium silicofluoride is sublimated from the surface of the substrate W, and the modified layer 130 is thereby removed from the surface of the substrate W.

After step S4, the controller 90 controls the gas supply 30, the exhaust assembly 40, and the heater 50 so as to increase the pressure in the processing chamber 10 to atmospheric pressure and lower the temperature in the processing chamber 10 to a discharge temperature. Next, the controller 90 controls the substrate processing apparatus 1 so as to lower the arm 25A and unload the boat 16 from the processing chamber 10. Thus, the processing of each substrate W held in the boat 16 is completed.

After step S4, the controller 90 may control the substrate processing apparatus 1 so as to form a silicon nitride film on the surface of each substrate W in the processing chamber 10. For example, the controller 90 controls the gas supply 30 and the heater 50 so as to non-simultaneously supply dichlorosilane gas and ammonia gas to the processing chamber 10 while the temperature of each substrate W in the processing chamber 10 is adjusted and maintained at a deposition temperature. Thus, a silicon nitride film can be formed on the surface of each substrate W. The deposition temperature may be equal to or greater than 400° C. and equal to or less than 800° C., for example, 630° C. The controller 90 may control the gas supply 30 so as to simultaneously supply dichlorosilane gas and ammonia gas to the processing chamber 10 while the temperature of each substrate W in the processing chamber 10 is adjusted and maintained at the deposition temperature.

As described above, according to the substrate processing method according to the present embodiment, the controller 90 controls the heater 50 so as to increase the temperature of each substrate W from the first temperature T1 to the second temperature T2 at a constant rate of temperature increase that is less than 10° C. per minute. In this case, when the temperature of each substrate W is increased, temperature unevenness is less likely to occur in the surface of each substrate W. Therefore, the ammonium silicofluoride contained in the modified layer 130 is easily sublimated uniformly in the surface of each substrate W. As a result, the surface roughness of the silicon nitride film 120 after etching can be reduced.

According to the substrate processing method according to the embodiment, during the increasing of the temperature of each substrate W from the first temperature T1 to the second temperature T2, the controller 90 controls the heater 50 so as to maintain the temperature of each substrate W in the processing chamber 10 at the third temperature T3, which is greater than the first temperature T1 and less than the second temperature T2, for a predetermined length of time. In this case, since the rapid temperature increase of each substrate W is reduced, temperature unevenness is less likely to occur in the surface of each substrate W when the temperature of each substrate W is increased. Therefore, the ammonium silicofluoride contained in the modified layer 130 is easily sublimated uniformly in the surface of each substrate W. As a result, the surface roughness of the silicon nitride film 120 after etching can be reduced.

### Experiment

In the experiment, the influence of the rate of temperature increase in step S3 of the substrate processing method on the surface roughness of the silicon nitride film after etching was evaluated. In the experiment, the surface layer of the silicon nitride film was etched according to the following procedure.

First, a substrate having a silicon nitride film on the surface was prepared and accommodated in the processing chamber 10 (step S1 in FIG. 3). Next, while the temperature of each substrate W in the processing chamber 10 was maintained at 75° C., hydrogen fluoride gas and ammonia gas were simultaneously supplied into the processing chamber 10 (step S2). Next, while nitrogen gas was supplied into the processing chamber 10, the temperature of each substrate W in the processing chamber 10 was increased from 75° C. to 300° C. at a constant rate of temperature increase (step S3). Next, while nitrogen gas was supplied into the processing chamber 10, the temperature of each substrate W in the processing chamber 10 was maintained at 300° C. In the experiment, the rate of temperature increase in step S3 was set at 10° C. per minute or 3° C. per minute.

Next, the shape of the surface of the silicon nitride film after etching was measured by atomic force microscopy (AFM), and the arithmetic mean roughness Ra was calculated.

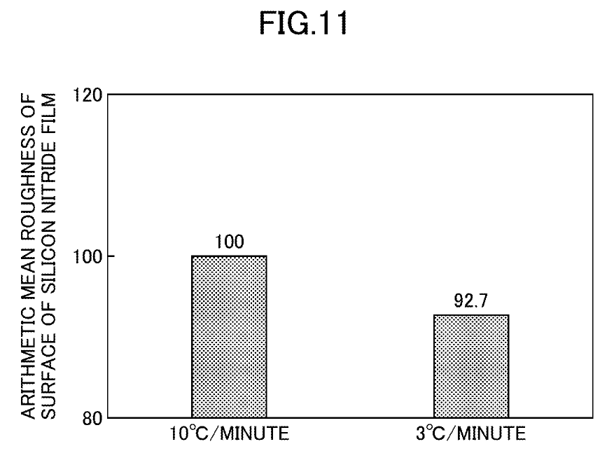

FIG. 11 illustrates the arithmetic mean roughness of the surface of the silicon nitride film after etching. In FIG. 11, the arithmetic mean roughness of the surface of the silicon nitride film when the rate of temperature increase was set at 10° C. per minute and 3° C. per minute is illustrated as a relative value when the arithmetic mean roughness of the surface of the silicon nitride film when the rate of temperature increase was set at 10° C. per minute was 100.

As illustrated in FIG. 11, when the arithmetic mean roughness of the surface of the silicon nitride film when the rate of temperature increase was set at 10° C. per minute was 100, the arithmetic mean roughness of the surface of the silicon nitride film when the rate of temperature increase was set at 3° C. per minute was 92.7. This result illustrates that the surface roughness of the silicon nitride film after etching can be reduced to a greater extent when the rate of temperature increase in step S3 is set to 3° C. per minute than when the rate of temperature increase in step S3 is set to 10° C. per minute.

The embodiments disclosed herein should be considered exemplary and not restrictive in all respects. The above embodiments may be omitted, substituted or modified in various ways without departing from the scope and intent of the appended claims.

In the foregoing embodiments, a case where the substrate processing apparatus is a batch-type apparatus for processing a plurality of substrates at a time has been described, but the present disclosure is not limited to this example. For example, the substrate processing apparatus may be a single-wafer type apparatus for processing substrates one by one.

In the above embodiments, a case where the film to be etched is a silicon nitride film has been described, but the present disclosure is not limited to this example. The film to be etched may be a nitride film other than a silicon nitride film. The film to be etched may be an oxide film, such as a silicon oxide film.

In the foregoing embodiments, the case where the silicon-containing gas is dichlorosilane gas is described, but the present disclosure is not limited to this example. The silicon-containing gas may be a silicon gas containing a halogen such as fluorine (F), chlorine (Cl), or bromine (Br). The fluorine-containing silicon gas may be, for example, SiF₄ gas, SiHF₃ gas, SiH₂F₂ gas, SiH₃F gas, or a combination of these gases. The chlorine-containing silicon gas may be, for example, SiCl₄ gas, SiHCl₃ gas, SiH₂Cl₂ gas, SiH₃Cl gas, Si₂Cl₆ gas, or a combination of these gases. The bromine-containing silicon gas may be, for example, SiBr₄ gas, SiHBr₃ gas, SiH₂Br₂ gas, SiH₃Br gas, or a combination of these gases.

In the foregoing embodiments, the nitriding gas is ammonia gas, but the present disclosure is not limited to this example. As the nitriding gas, for example, ammonia gas, diazene gas, hydrazine gas, monomethylhydrazine gas, trimethylamine gas, or a combination of these gases can be used.

In the foregoing embodiments, the basic gas is ammonia gas, but the present disclosure is not limited to this example. As the basic gas, for example, ammonia gas, dimethylamine gas, trimethylamine gas, hydrazine gas, or a combination of these gases can be used.

In the foregoing embodiments, the fluorine-containing gas is hydrogen fluoride gas, but the present disclosure is not limited to this example. As the fluorine-containing gas, for example, fluorine gas, chlorine trifluoride gas, nitrogen trifluoride gas, or a combination of these gases can be used.

What is claimed is:

1. A substrate processing method for removing a part of a film to be etched formed on a surface of a substrate, the method comprising:
forming a reaction product through a reaction between a surface layer of the film to be etched and both of a fluorine-containing gas and a basic gas by supplying the fluorine-containing gas and the basic gas to the substrate while a temperature of the substrate is maintained at a first temperature;
increasing the temperature of the substrate from the first temperature to a second temperature after the reaction product is formed; and
sublimating the reaction product while the temperature of the substrate is maintained at the second temperature, wherein
a rate of temperature increase at which the temperature of the substrate is increased from the first temperature to the second temperature is less than 10°C per minute.

2. The substrate processing method according to claim 1, wherein
the first temperature is equal to or greater than 50°C. and equal to or less than 100°C., and
the second temperature is equal to or greater than 200°C.

3. The substrate processing method according to claim 1, wherein
the film to be etched is a nitride film or an oxide film.

4. The substrate processing method according to claim 1, wherein
the fluorine-containing gas is a hydrogen fluoride gas, and
the basic gas is an ammonia gas.

5. A substrate processing method for removing a part of a film to be etched formed on a surface of a substrate, the method comprising:
forming a reaction product through a reaction between a surface layer of the film to be etched and both of a fluorine-containing gas and a basic gas by supplying the fluorine-containing gas and the basic gas to the substrate while a temperature of the substrate is maintained at a first temperature;
increasing the temperature of the substrate from the first temperature to a second temperature after the reaction product is formed; and
sublimating the reaction product while the temperature of the substrate is maintained at the second temperature, wherein
during the increasing of the temperature of the substrate from the first temperature to the second temperature, the temperature of the substrate is maintained at a third temperature, which is greater than the first temperature and less than the second temperature, for a predetermined length of time.

6. The substrate processing method according to claim 5, wherein a rate of temperature increase at which the temperature of the substrate is increased from the first temperature to the third temperature is less than 10°C. per minute, and
a rate of temperature increase at which the temperature of the substrate is increased from the third temperature to the second temperature is less than 10°C. per minute.

7. The substrate processing method according to claim 5, wherein
the first temperature is equal to or greater than 50°C. and equal to or less than 100°C., and
the second temperature is equal to or greater than 200°C.

8. The substrate processing method according to claim 5, wherein
the film to be etched is a nitride film or an oxide film.

9. The substrate processing method according to claim 5, wherein
the fluorine-containing gas is a hydrogen fluoride gas, and
the basic gas is an ammonia gas.

10. A substrate processing apparatus for removing a part of a film to be etched formed on a surface of a substrate, the substrate processing apparatus comprising a controller configured to control the substrate processing apparatus to perform:
forming a reaction product through a reaction between a surface layer of the film to be etched and both of a fluorine-containing gas and a basic gas by supplying the fluorine-containing gas and the basic gas to the substrate while a temperature of the substrate is maintained at a first temperature;
increasing the temperature of the substrate from the first temperature to a second temperature after the reaction product is formed; and
sublimating the reaction product while the temperature of the substrate is maintained at the second temperature, wherein
a rate of temperature increase at which the temperature of the substrate is increased from the first temperature to the second temperature is less than 10°C. per minute.
